(19) United States
(12) Patent Application Publication
(10) Pub. No.: US 2023/0334379 A1
(43) Pub. Date: Oct. 19, 2023

(54) ENERGY-EFFICIENT CAPACITANCE EXTRACTION METHOD BASED ON MACHINE LEARNING

(71) Applicant: ZHEJIANG UNIVERSITY, ZHEJIANG (CN)

(72) Inventors: Cheng ZHUO, Zhejiang (CN); Yuan Xu, ZHEJIANG (CN); Yu Qian, ZHEJIANG (CN); Chenyi Wen, ZHEJIANG (CN); Xunzhao YIN, ZHEJIANG (CN)

(73) Assignee: ZHEJIANG UNIVERSITY, ZHEJIANG (CN)

(21) Appl. No.: 18/189,191

(22) Filed: Mar. 23, 2023

(30) Foreign Application Priority Data
Apr. 14, 2022 (CN) 202210390710.4

(51) Int. Cl. G06N 20/20

(52) U.S. Cl. CPC G06N 20/20

(57) ABSTRACT

The present invention discloses an energy-efficient capacitance extraction method based on machine learning, and involves improving parameter extraction efficiency by using a machine learning model to extract parasitic capacitance; generally representing an interconnection line structure by grid-based data representation; reducing a workload of parameter extraction and enhancing the robustness of different semiconductor technologies with the idea of an adaptive extraction window; establishing a machine learning model of capacitance extraction for a two-dimensional interconnection line structure, and extracting grid parameters of a target interconnection line structure and inputting the grid parameters into the machine learning model, thereby obtaining parasitic capacitance parameters. Compared with an existing capacitance extraction technology, an capacitance extractor has achieved excellent performance in accuracy, speed and time and space consumption.

### CROSS-REFERENCE TO RELATED APPLICATION

This application claims the priority benefit of China application serial no. 202210390710.4, filed on Apr. 14, 2022. The entirety of the above-mentioned patent application is hereby incorporated by reference herein and made a part of this specification.

### BACKGROUND

### Technical Field

The present invention relates to the technical field of parasitic capacitance parameter extraction, and in particular to an energy-efficient capacitance extraction method based on machine learning.

### Description of Related Art

With continuous development of a semiconductor technology and continuous increase of a circuit scale, a parasitic capacitance between interconnection lines of conductors has more and more influence on the estimation of timing sequence. Especially under an advanced technology, the interconnection lines can not be simulated by simple cuboid metal lines, and the modelling accuracy and complexity of the interconnection lines are greatly improved, resulting in an rapid increase in the difficulty of capacitance parameter extraction. The extraction of the parasitic capacitance of the interconnection lines is the basis of important circuit index analysis such as circuit timing analysis, power consumption analysis, signal integrity analysis and power supply integrity analysis, and an accurate and quick parasitic capacitance extractor is crucial to ensuring the chip design quality, meeting strict requirements on power consumption, performance and area indexes and shortening a design period. This requires researchers to develop a more advanced high-performance solver to meet the chip design requirements currently and in the future.

The parasitic capacitance extractor calculates the parasitic capacitance between the interconnection lines by receiving information such as the arrangement of interconnection lines of a circuit (including a top view and a cross-sectional view), material parameters of the interconnection lines and electromagnetic parameters of a surrounding environment. The extractor often determines a certain conductor as a main conductor, and calculates a self-capacitance of the main conductor and a coupling capacitance between the main conductor and another conductor. With the development of a machine learning technology, it has been applied in a parasitic parameter extraction technology and has good performance. Where, an XGBoost machine learning model has the features of flexibility, high efficiency and portability, and shows a great potential in specific applications in various fields.

The prior art is mainly divided into three steps: firstly, massive interconnection line structures are subjected to accurate capacitance calculation and collective parameter extraction to form a pattern library; secondly, geometric parameter extraction is performed on a target interconnection line structure needed to be calculated; and finally, geometric parameters of a target structure are matched with items in the pattern library to calculate the capacitance.

The main deficiencies of an existing technology are as follows: 1. with the increasing complexity of a semiconductor technology, the establishment of the pattern library is facing great challenges, advanced technological structures such as a low dielectric constant medium, a non-vertical interface conductor and a bubble medium lead to reduction of the modeling accuracy and substantial increase of modeling time of the interconnection lines. 2. The increase of a chip scale means that a workload of extracting geometric parameters of the target interconnection line structure is greatly increased, which will occupy a lot of calculation time and space. 3. There may be pattern mismatch in an existing method, that is, the target interconnection line structure can not find a pattern matched therewith in the pattern library, and only an approximate solution can be obtained. The accumulation of these errors will greatly affect the accuracy of parasitic capacitance extraction.

Based on the above problems, in order to improve the efficiency and universality of a parasitic capacitance extraction technology, an energy-efficient capacitance extraction method based on machine learning is proposed.

### SUMMARY

Aiming at solving the problems that an existing full-chip extraction method based on pattern matching has large errors and complicated processes, the present invention proposes a machine learning method for establishing a neural network capacitance model for a two-dimensional structure in full-chip capacitance extraction through a new grid-based data representation and an idea of an adaptive extraction window, and designs an energy-efficient capacitance extractor based on FasterCap and combined with an XGBoost machine learning model. The total capacitance error and the coupling capacitance error generated by this method are within a reasonable range, so that excellent performance and better universality are shown.

The objective of the present invention is achieved by the following technical solution.

An energy-efficient capacitance extraction method based on machine learning comprises the following steps:
a data set preparation stage: randomly generating enough input samples with different conductor arrangements under different technological standards, and inputting the input samples into a FasterCap tool after the input samples are subjected to data preprocessing, and taking FasterCap output data as XGBoost labels; meanwhile, with a two-dimensional cross-sectional structure regarded as an image, characterizing an arbitrary arrangement mode of any number of conductors as a respective two-dimensional matrix by using an adaptive window extraction and gridding method, thereby obtaining input of XGBoost from the randomly generated input samples;
machine learning model training: combining XGBoost input and the XGBoost labels are combined into a data set, performing training is performed with a large number of data sets respectively to obtain two XGBoost machine learning models of self-capacitance and coupling capacitance;
problem solving: taking a two-dimensional cross-sectional structure of a chip whose capacitance is to be extracted as an input of a capacitance extractor according to the same adaptive window extraction and gridding method, and obtaining a self-capacitance of a main conductor and a coupling capacitance between the main conductor and an adjacent conductor at an output end of the capacitance extractor, thereby realizing parasitic capacitance extraction of the full chip.

Furthermore, a size of an adaptive window is determined by reducing the coupling capacitance between an environmental conductor and the main conductor to 1% of the self-capacitance of the main conductor in a simulation experiment.

Further, a structural model of three metal layers is considered when data representation is gridded, the main conductor is located in a center of a middle layer, and the number of conductors in each layer is not fixed.

Further, a grid is uniformly divided, each conductor layer is represented as a vector x according to a density, in which information of the main conductor and the environmental conductor is contained through the following encoding mode:
if the main conductor covers the ith grid, then xᵢ=dᵢ+1;
if the environmental conductor covers the ith grid, then xᵢ=−dᵢ;
where, dᵢ represents a density of an extraction window.

Further, the capacitance extraction method using XGBoost machine learning is realized by off-line training.

The present invention has the beneficial effects that the present invention provides an energy-efficient capacitance extraction method based on machine learning, and the proposed grid representation method based on the adaptive window selects a size of the capacitance extraction window matched with a feature size according to the feature size which is as small as possible, so that the arbitrary arrangement of any number of conductors can be effectively represented, and important information such as the main conductor and the corresponding environmental conductor whose mutual capacitance needs to be calculated can be successfully marked. The extraction of the adaptive window reduces the number of grids by 3 or 4 orders of magnitude. Meanwhile, the gridded vector using “conductor-occupying-grid ratio” as an element has higher information entropy than that using pixel representation, which will lead to a simpler machine learning model input and a more feasible machine learning architecture, and then the self-capacitance and mutual capacitance of the full chip can be extracted quickly and accurately through the machine learning model. Such preprocessing means is a standardization process and can process a plurality of inputs in batch in an executable script mode, and a processing process has no relation with input contents. The time complexity and the space complexity of this process relative to the number of conductors are both O(1), so that it is very suitable for a large-batch and repeated capacitance extraction process. In addition, “gridded data representation” has very high expansibility and adjustability, and the size and quantity of grids can be adjusted for different technologies, thus being suitable for our proposed capacitance extraction method based on the XGBoost machine learning model. Under the condition of an ultra large scale integrated circuit and the advanced technology, compared with a traditional full-chip extraction method based on pattern matching, the capacitance extractor based on machine learning proposed by the present invention has very high accuracy and speed, can quickly calculate capacitance parameters of the full chip, has very small error, occupies less memory and reduces energy consumption to a great extent.

### BRIEF DESCRIPTION OF THE DRAWINGS

FIG. 1 is a flowchart of the present invention;

FIG. 2 is a structural diagram of a two-dimensional metal layer of a chip of the present invention;

FIG. 3 is an example diagram of a grid representation method proposed by the present invention; and

FIG. 4 is a result diagram of capacitance extraction based on machine learning in an embodiment of the present invention.

### DESCRIPTION OF THE EMBODIMENTS

Specific embodiments of the present invention will be further described in detail with reference to the accompanying drawings.

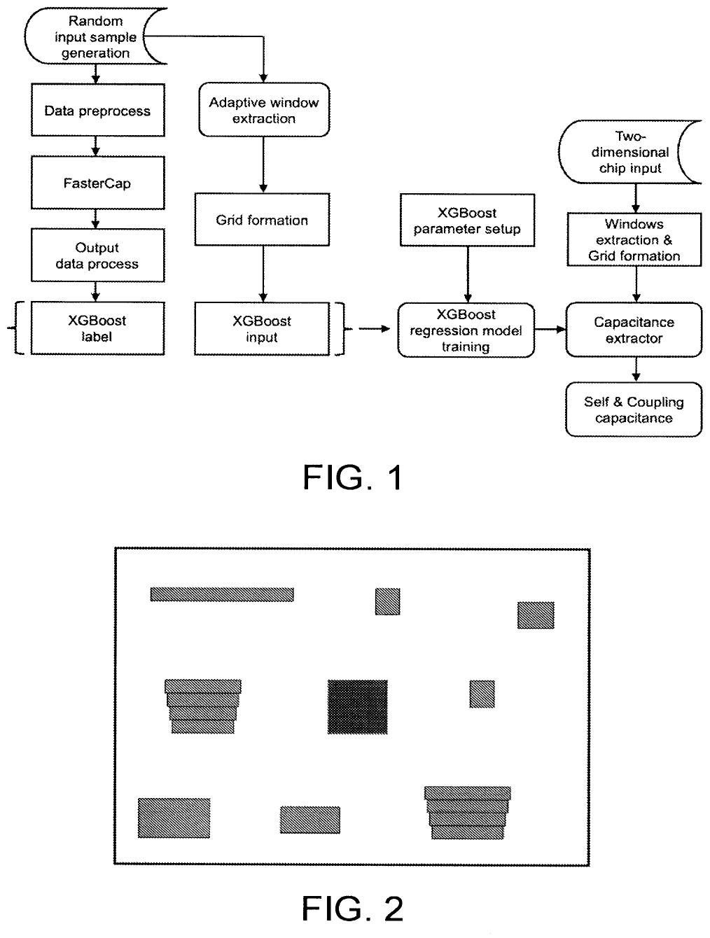

As shown in FIGS. 1-4, an energy-efficient capacitance extraction method based on machine learning provided by the present invention comprises the following specific implementation steps:

1) Data set preparation stage

Enough input samples with different conductor arrangements under different technological standards are randomly generated, and machine learning data sets are generated by the following methods:

1.1) randomly generated samples are input into a FasterCap tool after being subjected to data preprocessing, and FasterCap calculation is performed after dielectric parameters are reasonably set, an obtained capacitance matrix can get more accurate capacitance value after certain data processing, and a difference between the capacitance value and test sample data is less than 2%. Therefore, it is considered that the calculation accuracy of FasterCap is acceptable and it can be used as a reference tool to generate labels of data sets to train the XGBoost machine learning model.

1.2) with a two-dimensional cross-sectional structure regarded as an image, the influence of the coupling capacitance between a main conductor and a conductor at a relatively long distance can be ignored, and a size of an extraction window is set according to the condition that the coupling capacitance between an environmental conductor and the main conductor is less than 1% of the self-capacitance of the main conductor.

As shown in FIG. 2, a structural model of three metal layers is considered, the main conductor is located in a center of a middle layer, and the number of conductors in each layer is not fixed. The conductor pattern can be a rectangle or a connected rectangle (vertically connected to approximate a trapezoid in the advanced technology). This model can be easily extended to a structure with more than three metal layers. A width of the extraction window is evenly divided into L1 grid units and a height is evenly divided into L2 grid units, so that the conductor distribution in the area of the extraction window can be described by L1×L2 dimension vectors. Then a density of the extraction window is expressed as: d ∈ R^{L}, and a value of a vector element dᵢ is the density, that is, a ratio of the conductor to a certain grid unit.

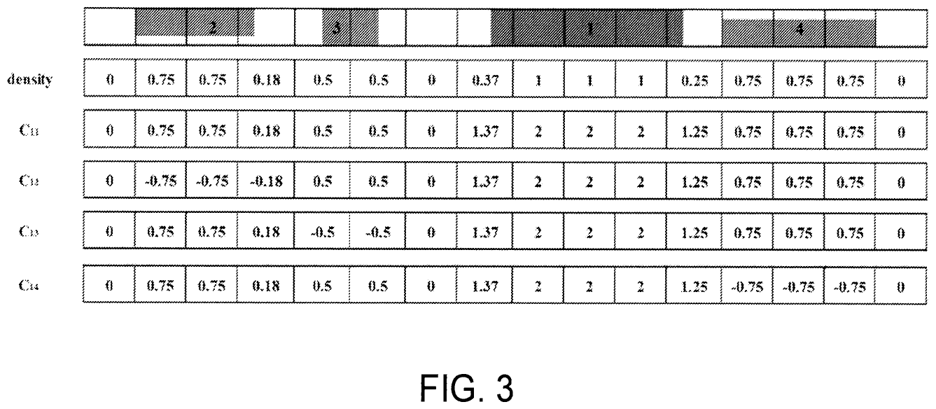

Assuming that the structure includes n conductors, it is necessary to extract one self-capacitance and n-1 coupling capacitances, but this grid-based representation method cannot identify the main conductor. In order to encode more information about the main conductor and the environmental conductor therein, the present invention modifies the structure, and if the main conductor covers the ith grid, then xᵢ=dᵢ+1. In order to calculate the coupling capacitance between the main conductor and the environmental conductor, in addition to adding 1 to an element corresponding to a unit overlapping with a main unit, if the environmental conductor covers the ith grid, let xᵢ=−dᵢ. As shown in FIG. 3, a first row is a density vector d, a second row is a characteristic vector when the self-capacitance of the main conductor is calculated, and the third, fourth and fifth rows are characteristic vectors when the coupling capacitance between the main conductor and the environmental conductor is calculated.

2) Machine learning model training

Because the total capacitance and the coupling capacitance differ by several orders of magnitude and have different precision requirements, in order to ensure the overall precision of capacitance extraction, the present invention trains the two XGBoost machine learning models of self-capacitance and coupling capacitance respectively through XGBoost data sets comprising the input and the labels obtained above.

In XGBoost training, a forward distribution algorithm is used for greedy learning, and a CART tree is learned in each iteration to fit a residual between a prediction result of a previous (t-1)th tree and a true value of a training sample. When K trees are obtained after the training is completed, it is necessary to predict a score of one sample. According to the characteristics of this sample, it will fall to a corresponding leaf node in each tree, and each leaf node will correspond to a score. Finally, it only needs to add up the scores corresponding to the respective trees to obtain a predicted value of this sample.

For each extension, all possible solutions need to be enumerated. For a specific segmentation, the sum of a derivative of a left subtree and a derivative of a right subtree is calculated and compared with that before the segmentation. All segmentations are traversed, and the one with the greatest change is chosen as the most suitable segmentation.

In the present invention, a library function of an XGBoost library is adopted to perform model training. Firstly, a training set and a test set are reasonably divided, and then two XGBoost models of self-capacitance and mutual capacitance extraction are trained by parameter tuning. The specific methods of parameter tuning are as follows:

2.1) A learning rate and a number of trees are determined: a higher learning rate is selected. In general, a value of the learning rate is 0.1. However, for different issues, the ideal learning rate sometimes fluctuates between 0.05 and 0.3. The number of ideal decision trees corresponding to this learning rate is selected.

2.2) For a given learning rate and number of decision trees, tuning of decision tree specific parameters is performed. max_depth and min_weight parameter tuning: these two parameters are tuned first because they have great influence on a final result; gamma parameter tuning: the purpose is to reduce the risk of over-fitting, with an optional range being 0 to 0.5; adjusting sampling methods subsample and colsample_bytree. For the above parameters, a grid search method is adopted, coarse tuning of the parameters in a large range is performed, and then fine tuning in a small range is performed.

2.3) Tuning of regularization parameters (lambda, alpha) of XG Boost is performed. These parameters can reduce the complexity of the model, thus improving the performance of the model.

2.4) Reduction of learning rate: a lower learning rate and more decision trees are used. The present invention uses a CV function in XGBoost to perform this step.

3) Features are extracted from a two-dimensional structure of a chip whose capacitance is to be extracted by the same adaptive window extraction and gridding method, and are input into the trained XGBoost model, so that the self-capacitance of the main conductor and the coupling capacitance between the main conductor and an adjacent conductor can be solved, thereby realizing parasitic capacitance extraction of the full chip.

The model obtained after training with the present invention is used to perform capacitance extraction on an ultra large scale integrated circuit and chips with different conductor arrangements under different technological standards in the advanced technology, and has the characteristics of fast running and small memory footprint. Because the XGBoost machine learning model adopts an off-line training mode, the training time will not affect the time complexity of running of the capacitance extractor. Meanwhile, memory consumption at runtime and a storage space needed to train the model are very small.

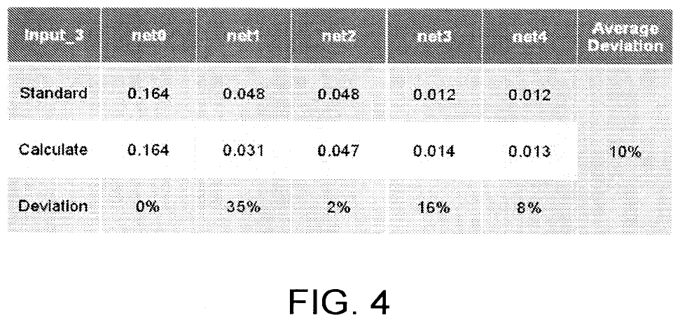

In this embodiment, the chip under the Input_3 technological standard is subjected to capacitance extraction, wherein net0 is the main conductor, net1 and net2 are adjacent conductors. The results and deviations are shown in FIG. 4, from which it can be seen that self-capacitance results are relatively accurate.

It should be noted that the above-mentioned embodiments merely illustrate rather than limit the present invention, and that those skilled in the art will understand that, although the present invention has been described in detail with reference to the preferred embodiments, the technical solutions of the present invention can be modified and substituted by equivalents without departing from the spirit and scope of the technical solutions, which should be included in the scope of the claims of the present invention.

What is claimed is:

1. An energy-efficient capacitance extraction method based on machine learning, comprising following steps of:
a data set preparation stage: randomly generating enough input samples with different conductor arrangements under different technological standards, and inputting the input samples into a FasterCap tool after the input samples are subjected to data preprocessing, and taking FasterCap output data as XGBoost labels; meanwhile, with a two-dimensional cross-sectional structure regarded as an image, characterizing an arbitrary arrangement mode of any number of conductors as a respective two-dimensional matrix by using an adaptive window extraction and gridding method, thereby obtaining input of XGBoost from the input samples randomly generated;
machine learning model training: combining XGBoost input and the XGBoost labels into a data set, performing training with a large number of data sets respectively to obtain two XGBoost machine learning models of self-capacitance and coupling capacitance;
problem solving: taking a two-dimensional cross-sectional structure of a chip whose capacitance is to be extracted as an input of a capacitance extractor according to the adaptive window extraction and gridding method, and obtaining a self-capacitance of a main conductor and a coupling capacitance between the main conductor and an adjacent conductor at an output end of the capacitance extractor, thereby realizing parasitic capacitance extraction of a full chip.

2. The energy-efficient capacitance extraction method based on machine learning according to claim 1, wherein a size of an adaptive window is determined by reducing the coupling capacitance between an environmental conductor and the main conductor to 1% of the self-capacitance of the main conductor in a simulation experiment.

3. The energy-efficient capacitance extraction method based on machine learning according to claim 1, wherein a structural model of three metal layers is considered when data representation is gridded, the main conductor is located in a center of a middle layer, and a number of conductors in each layer is not fixed.

4. The energy-efficient capacitance extraction method based on machine learning according to claim 1, wherein a grid is uniformly divided, each conductor layer is represented as a vector x according to a density, in which information of the main conductor and an environmental conductor is contained through the following encoding mode:
if the main conductor covers the ith grid, then xᵢ=dᵢ+1;
if the environmental conductor covers the ith grid, then xᵢ=−dᵢ;
where, dᵢ represents a density of an extraction window.

5. The energy-efficient capacitance extraction method based on machine learning according to claim 1, wherein the energy-efficient capacitance extraction method using XGBoost machine learning is realized by off-line training.
